(19) United States
(12) Patent Application Publication
(10) Pub. No.: US 2002/0084816 A1
(43) Pub. Date: Jul. 4, 2002

(54) Precision phase generator

(76) Inventor: William A. Harris, Coon Rapids, MN (US)

Correspondence Address: HONEYWELL INTERNATIONAL INC., 101 COLUMBIA ROAD, P O BOX 2245, MORRISTOWN, NJ, 07962-2245, US

(21) Appl. No.: 09/751,610

(22) Filed: Dec. 29, 2000

(51) Int. Cl. H03L 7/06

(52) U.S. Cl. 327/159

(57) ABSTRACT

A precision multiphase clock signal generator for providing a plurality of clock signals precisely phase shifted from each other. The clock signals are taken from the outputs of shift registers in a Johnson counter in the feedback path of a phase lock loop circuit.

### TECHNICAL FIELD

Electronic control systems, particularly precision phase generators for generating multiple phase clocking signals from a single phase clock signal.

### BACKGROUND OF THE INVENTION

In computer and other systems, a single oscillator produces a signal that is used as the source of clock and control signals to control the operation of various storage elements and latches elements in the system. Often it is found to be desirable to clock these elements using different phases of a clock signal. While a number of techniques have been used to generate two different clock pulse signal phases, such designs do not provide more than two phases from a single high frequency clock. Since it is often desirable to provide four or more different phases of a clock signal with precise phase relationships to control a wide variety of storage elements in a circuit, there is a need for a multiple phase providing two or more phases of a clock signal from a single high frequency clock. Such needs are satisfied by the present invention. cl SUMMARY OF THE INVENTION

The present invention is directed to a multiple phase signal generator. It provides a circuit for dividing an input clock signal into N clock signals having a relative phase separation of 360°/2N clock signals, where N is a positive integer. The circuit has a phase lock loop circuit receiving an input signal having a frequency F₀ and providing an output signal having a frequency 2NF₀ and a Johnson counter having N stages connected to receive as an input the output signal of the phase lock loop circuit and providing an output signal as an error signal to the phase lock loop circuit. The Johnson counter is also connected for providing at least two output signals from each of the N stages of the Johnson counter as clock signals each having a phase displaced from the phase of the other 360/2N°.

A circuit for receiving an input clock signal and generating a plurality of clock signals having frequencies identical to the input clock signal and predetermined phase displacements from the input signal. The circuit has a phase detector for comparing an input clock signal to a feedback signal and providing an output signal corresponding to the phase difference between the input clock signal and the feedback signal. It also has a low pass filter and gain stage receiving the output signal from the phase comparator and producing a control signal and a voltage controlled oscillator for receiving the control signal and producing an oscillator output signal having a frequency corresponding to the control signal. A multistage counting circuit is connected to receive the oscillator output signal and provide the feedback signal to the phase detector and a plurality of clock signals at the frequency of the input clock signal and phase shifted from the clock signal by fixed angular increments.

According to another feature of the present invention a method is provided for generating at least two clock signals displaced from each other by a predetermined phase shift of 360°/2N, where N is a positive integer. The method includes applying a clock signal to a signal input of a phase lock loop circuit at the desired clock frequency and applying a feedback signal to the other input of the phase lock loop and generating an output of the phase lock loop having a frequency of 2N. The method further provides for coupling the output of the phase locked loop to an N stage Johnson counter to provide a signal to the other input of the phase shift loop having a frequency corresponding to the frequency of the output signal of the phase locked loop divided by 2N and coupling the outputs of the stages of the Johnson counter for use as phase shifted clock outputs.

Other features and advantages of the present invention will become evident hereinafter.

### BRIEF DESCRIPTION OF THE DRAWINGS

FIG. 1 is a block diagram of an embodiment of a precision multiple phase generator; and

FIG. 2 is a block diagram of an embodiment of a precision multiple phase generator providing clock signals separated from each other by 45 degrees.

### DESCRIPTION OF THE PREFERRED EMBODIMENT

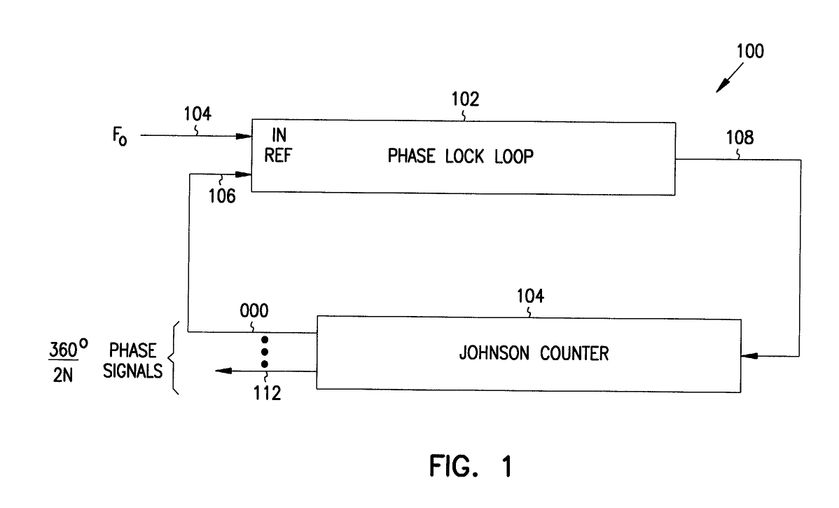

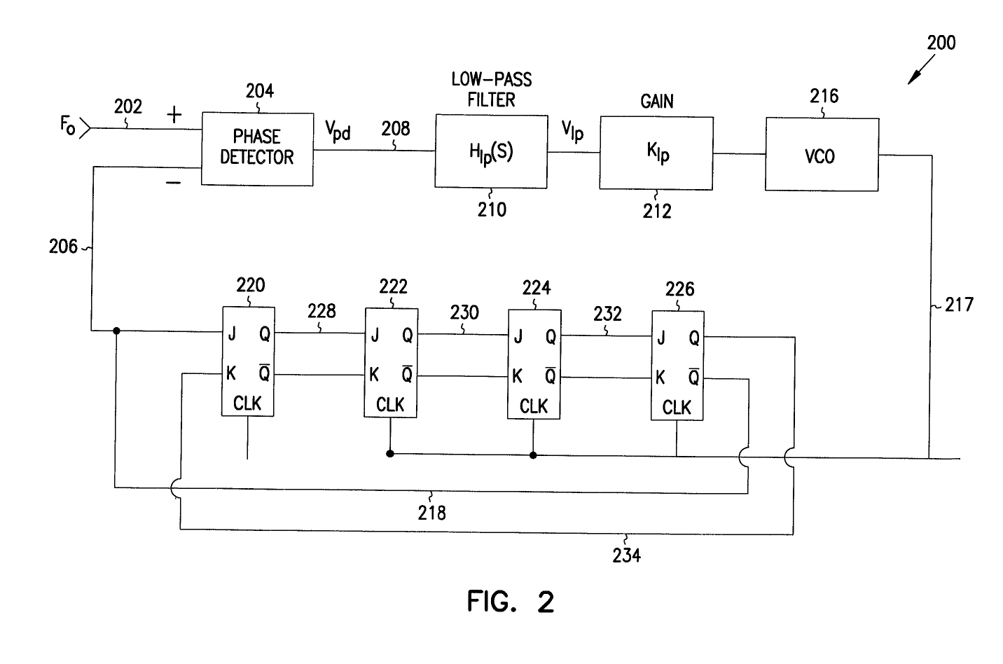

The following detailed description, which references and incorporates FIGS. 1 and 2, describes and illustrates specific embodiments of the invention. These embodiments, offered not to limit but only to exemplify and teach the concepts of the invention, are shown and described in sufficient detail to enable those skilled in the art to implement or practice the invention. Thus, where appropriate to avoid obscuring the invention, the description may omit certain information known to those of skill in the art.

### Exemplary System Incorporating Invention

FIG. 1 shows an exemplary precision phase generator 100 incorporating the present invention. Phase generator 100 includes a phase lock loop circuit 102 and a Johnson counter 104.

Phase lock loop circuit 102 receives an input signal 104 having a frequency F₀ from a clock source. In phase lock loop 102, input signal 104 is compared to a reference signal which is applied to a reference input terminal 106 of phase lock loop 102 and an internal error signal is developed. The internal phase error signal is conditioned by a gain stage and a low pass filter to provide a control signal which is applied to the input of a voltage controlled oscillator which provides an output signal 108 which corresponds to the control signal.

The output signal 108 from the voltage controlled oscillator of phase lock loop 102 is connected to an input of Johnson counter 104. A Johnson counter is a specific form of shift register with a specific feedback to its serial input such that whatever the state of the output stage, the complement of that state is applied to the serial input at the next clock pulse. For a Johnson counter with four stages, n=4, the cycle length is 2n rather than 2ⁿ. Hence, for a four stage counter the cycle length is 2n=8 rather than 2n=16. An output 110 of Johnson counter 104 is taken from the nth flip flop stage of the counter so that its frequency is F₀.

In order to have the error signal at terminal 106 correspond to input clock signal F₀, it is necessary that the gain of the voltage controlled oscillator be set so that the output of phase lock loop 102 is 2n*F₀. Additional outputs 112 are provided from each of the shift registers of Johnson counter 104. Each of those outputs has the same frequency as clock signal F₀ but are each shifted in phase by 360°/2N from clock signal F₀.

A more complete block diagram of an embodiment of a precision phase generator 200 according to the present invention is shown in FIG. 2. An input clock signal 202 having a frequency F₀ is applied to an input terminal 202 of a phase detector 204. Phase detector 204 compares the phase of the input signal at terminal 202 to an error signal received at terminal 206 and provides an output signal at output terminal 208 which has an average value corresponding to the phase difference between the input signals at terminals 202 and 206.

The output signal from phase detector 204 is received by low pass filter 210 and gain stage 212 which produce a control signal which is connected to an input terminal 214 of a voltage controlled oscillator 216. Voltage controlled oscillator 216 produces an oscillator output voltage having a frequency corresponding to the control voltage. More specifically, the output signal 217 of oscillator 216 has a frequency which is scaled such that the output at terminal 218 of the Johnson counter formed of shift registers 220, 222, 224 and 226 has a frequency corresponding to the frequency of input clock signal F₀. Thus, for the four stage Johnson counter illustrated, the frequency of input F₀ of the oscillator output signal from voltage controlled oscillator 216 is multiplied by 2n or 8.

The frequency of the signal at output 218 of the Johnson counter formed of registers 220, 222, 224 and 226 is ½n or ⅛ the frequency of output signal 217 due to the scaling or dividing action of the counter. The counter output signal is connected to the error input terminal 206 of phase detector 204 to close the loop of the phase lock loop so that the signal at output 218 of the Johnson counter is locked to the frequency F₀ of input clock signal 202.

Multiple clock output signals having frequencies identical to frequency F₀ of input clock signal 202 are available on terminals 228, 230 and 232 as well as on terminal 218. In order to have counters 220, 222, 224 and 226 function as a Johnson counter, a feedback connection is made from output terminal 218 to an input of the first shift register 220 so that whatever the state of output stage 226, the complement of that state is applied to the serial input of the Johnson counter at the next clock pulse.

In the circuit shown in FIG. 2, the phase difference between signals at at terminals 228 and 230, 230 and 232, 232 and 234 is precisely 45 degrees. Thus these four outputs and the complemented outputs of the respective counter stages provide eight precise internal clock signals separated by precisely 45 degrees from each other and covering the full 360 degree phase range. For a pulse generator with a divide by four rather than a divide by eight counter, as shown, the phase differences between the terminals would be 90 degrees. It can be seen that by appropriately designating n, it is possible to set a wide variety of possible phase shifts between the multiple of clock signals that may be produced by the precision phase generator.

In furtherance of the art, the inventor has presented new methods as well as circuits embodying these methods, for precision generating multiple phase shifted clock signals. One exemplary non-iterative method for generating at least two clock signals displaced from each other by a predetermined phase shift of 360°/2N, where N is a positive integer calls for applying a clock signal to a signal input of a phase lock loop circuit at the desired clock frequency and applying a feedback signal to the other input of the phase lock loop. It also involves generating an output of the phase lock loop having a frequency of 2N, coupling the output of the phase locked loop to an N stage Johnson counter to provide a signal to the other input of the phase lock loop having a frequency corresponding to the frequency of the output signal of the phase locked loop divided by 2N and coupling the outputs of the stages of the Johnson counter for use as phase shifted clock outputs.

The embodiments described above are intended only to illustrate and teach one or more ways of practicing or implementing the present invention, not to restrict its breadth or scope. The actual scope of the invention, which embraces all ways of practicing or implementing the teachings of the invention, is defined only by the following claims and their equivalents.

1. A circuit for dividing an input clock signal into N clock signals having a relative phase separation of 360°/2N clock signals, where N is a positive integer, the circuit comprising:
a phase lock loop circuit receiving an input signal having a frequency F₀ and providing an output signal having a frequency 2NF₀; and
a Johnson counter having N stages connected to receive as an input the output signal of the phase lock loop circuit and providing an output signal as an error signal to the phase lock loop circuit; said Johnson counter also connected for providing at least two output signals from at least two of the N stages of the Johnson counter as clock signals each having a phase displaced from the phase of the other 360/2N°.

2. The circuit of claim 1 wherein N=4.

3. The circuit of claim 1 wherein N=8.

4. A circuit for providing multiple clock signals phase shifted from each other, the circuit comprising:
a phase lock loop circuit comparing an input signal and an error signal and providing an output signal; and
a multi-stage counter connected in the feedback path of the phase lock loop circuit to receive as an input the output signal of the phase lock loop circuit and providing an output signal as the error signal to the phase lock loop circuit; said counter also connected for providing at least two output signals from each of the stages of the counter as clock signals each having a phase displaced from the phase of the input signal.

5. The circuit of claim 4 wherein the multi-stage counter is a Johnson counter having N stages and where the frequency of the output signal of the Johnson counter is the frequency of the output signal of the phase lock loop circuit divided by 2N.

6. A circuit for receiving an input clock signal and generating a plurality of clock signals having frequencies identical to the input clock signal and predetermined phase displacements from the input signal, comprising:
a phase detector for comparing an input clock signal to a feedback signal and providing an output signal corresponding to the phase difference between the input clock signal and the feedback signal;
a low pass filter and gain stage receiving the output signal from the phase comparator and producing a control signal;
a voltage controlled oscillator for receiving the control signal and producing an oscillator output signal having a frequency corresponding to the control signal; and
a multistage counting circuit connected to receive the oscillator output signal and provide the feedback signal to the phase detector and a plurality of clock signals at the frequency of the input clock signal and phase shifted from the clock signal by fixed angular increments.

7. The circuit of claim 6 wherein the output signal of the phase detector represents the phase difference between the input clock signal and the feedback signal.

8. The circuit of claim 6 wherein the frequency of the voltage controlled oscillator output signal is a multiple of the frequency of the input clock signal.

9. The circuit of claim 8 wherein multistage counting circuit is a Johnson counter having N stages.

10. The circuit of claim 6 wherein the frequency of the voltage controlled oscillator output signal is a multiple of the frequency of the input clock signal.

11. A circuit for generating multiphase clock signals, the circuit comprising:
a clock generator for generating a first clock signal at a clock frequency F₀;
a phase lock loop circuit receiving the first clock signal and providing an output signal; and
a Johnson counter having N stages connected to receive as an input the output signal of the phase lock loop circuit and providing an output signal as an error signal to the phase lock loop circuit; said Johnson counter also connected for providing output signals from each of the N stages of the Johnson counter as further clock signals.

12. The circuit of claim 11 wherein the output signal of the phase lock loop circuit has a frequency of 2N*F₀.

13. A multiphase signal generator circuit, comprising:
a generator for generating a clock signal having a clock frequency;
a phase detector for comparing the clock signal to a feedback signal and providing an output signal corresponding to the phase difference between the clock signal and the feedback signal;
a low pass filter and gain stage receiving the output signal from the phase comparator and producing a control signal;
a voltage controlled oscillator for receiving the control signal and producing an oscillator output signal having a frequency corresponding to the control signal; and
a multistage counting circuit connected to receive the oscillator output signal and provide the feedback signal to the phase detector and a plurality of clock signals at the clock frequency and phase shifted from the clock signal.

14. The circuit of claim 13 wherein the plurality of clock signals from the multistage counting circuit are shifted from each other by fixed angular increments.

15. The generator circuit of claim 13 wherein the multistage counting circuit is a Johnson counter having N stages.

16. The circuit of claim 13 wherein the output signal of the phase detector represents the phase difference between the input clock signal and the feedback signal.

17. The circuit of claim 13 wherein the frequency of the voltage controlled oscillator output signal is a multiple of the frequency of the input clock signal.

18. The circuit of claim 13 wherein multistage counting circuit is a Johnson counter having N stages.

19. The circuit of claim 9 wherein the frequency of the voltage controlled oscillator output signal is a multiple of the frequency of the input clock signal.

20. A method for generating at least two clock signals displaced from each other by a predetermined phase shift of 360°/2N, where N is a positive integer, the method comprising:
applying a clock signal to a signal input of a phase lock loop circuit at the desired clock frequency;
applying a feedback signal to the other input of the phase lock loop;
generating an output of the phase lock loop having a frequency of 2N
coupling the output of the phase locked loop to an N stage Johnson counter to provide a signal to the other input of the phase shift loop having a frequency corresponding to the frequency of the output signal of the phase locked loop divided by 2N; and
coupling the outputs of the stages of the Johnson counter for use as phase shifted clock outputs.

21. The method of claim 20 wherein N=4.
